(19) United States
(12) Patent Application Publication
(10) Pub. No.: US 2023/0209780 A1
(43) Pub. Date: Jun. 29, 2023

(54) DATA CENTER HAVING RACK CLUSTERS WITH HIGH DENSITY, AIR-COOLED SERVER RACKS

(71) Applicant: NVIDIA Corporation, Santa Clara, CA (US)

(72) Inventor: Alex R. Naderi, Santa Clara, CA (US)

(21) Appl. No.: 18/175,536

(22) Filed: Feb. 28, 2023

Related U.S. Application Data
(63) Continuation of application No. 16/809,367, filed on Mar. 4, 2020.
(60) Provisional application No. 62/815,840, filed on Mar. 8, 2019.

(51) Int. Cl. H05K 7/20; H05K 7/14

(52) U.S. Cl. CPC H05K 7/20736; H05K 7/1488; H05K 7/20745

(57) ABSTRACT

The disclosure provides a data center with high density server racks that are solely air cooled. A data center comprises a processor to use one or more computational fluid dynamics (CFD) models to indicate a placement of one or more servers within one or more server racks to substantially maintain a temperature within the one or more server racks during operation without using additional cooling sources.

### CROSS-REFERENCE TO RELATED APPLICATION

This application is a continuation application of U.S. application Ser. No. 16/809,367, filed Mar. 4, 2020, which claims the benefit of U.S. Provisional Application Ser. No. 62/815,840, filed Mar. 8, 2019, both of which are incorporated herein by reference.

### TECHNICAL FIELD

This disclosure is directed, in general, to data centers and, more specifically, to designing and employing high power density, air-cooled server racks in data centers.

### BACKGROUND

Many organizations use large scale computing facilities, such as data centers, in their business. These data centers include multiple servers, networks, and computer equipment to process, store, and exchange data as needed to carry out an organization's operations. Traditionally the servers have been Central Processing Unit (CPU) driven servers (hereinafter CPU based servers). The CPU based servers are usually mounted in racking systems or racks and are located in a data hall of a data center. The data hall is filled with the server racks to satisfy the need for processing power. With the addition of more server racks, additional cooling is often required.

### SUMMARY

In one aspect, a data center is disclosed. In one embodiment, the data center includes: (1) a cooling system that provides a cold air supply; and (2) a rack cluster including multiple server racks rated at greater than 20 kW, wherein each of the multiple server racks has a front side facing the cold air supply and a back side, and each of the multiple server racks are solely cooled by air moving therethrough from the front side to the back side.

In another aspect, the disclosure provides a method of converting an area of a data center from low density server racks to high density server racks, wherein the area employs an air cooling system for cooling the low density server racks. In one embodiment, the method includes: (1) removing low density server racks located in the area, (2) adding one or more high density server racks to the area, wherein the one or more high density server racks are part of at least one rack cluster, and (3) solely employing the air cooling system for cooling the at least one rack cluster.

In yet another aspect, a method of installing high density, air-cooled server racks within a data center is disclosed. In one embodiment, this method includes: (1) receiving a power specification for a high density server rack and an air cooling specification for a data center, (2) determining a rack cluster for multiple high density racks based on the power specification and the air cooling specification, and (3) arranging the multiple high density racks in the rack cluster employing Computational Fluid Dynamic (CFD) modelling.

### BRIEF DESCRIPTION

Reference is now made to the following descriptions taken in conjunction with the accompanying drawings, in which:

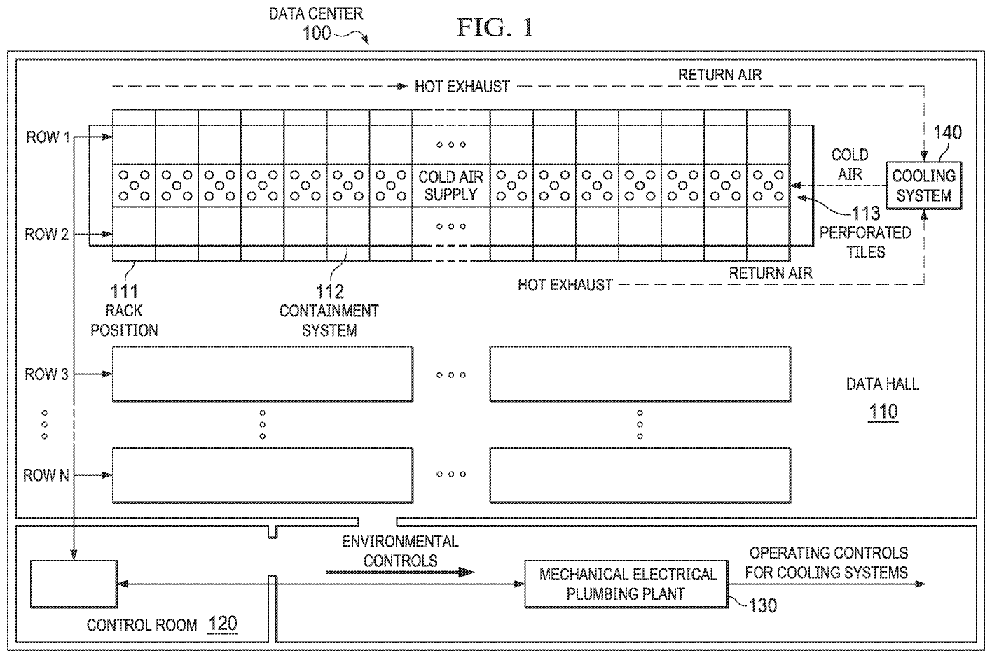

FIG. 1 illustrates a diagram of an embodiment of a data center having an area for conversion from low density server racks to air-cooled, high density server racks using rack clusters according to the principles of the disclosure;

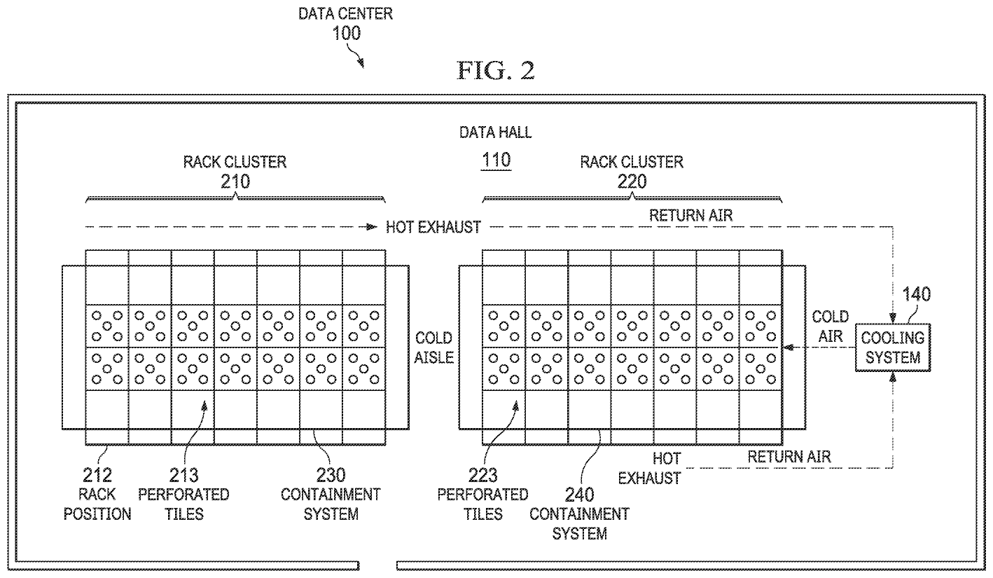

FIG. 2 illustrates a diagram of an embodiment of a data hall of the data center of FIG. 1 having rack clusters of air-cooled, high density server racks according to the principles of the disclosure;

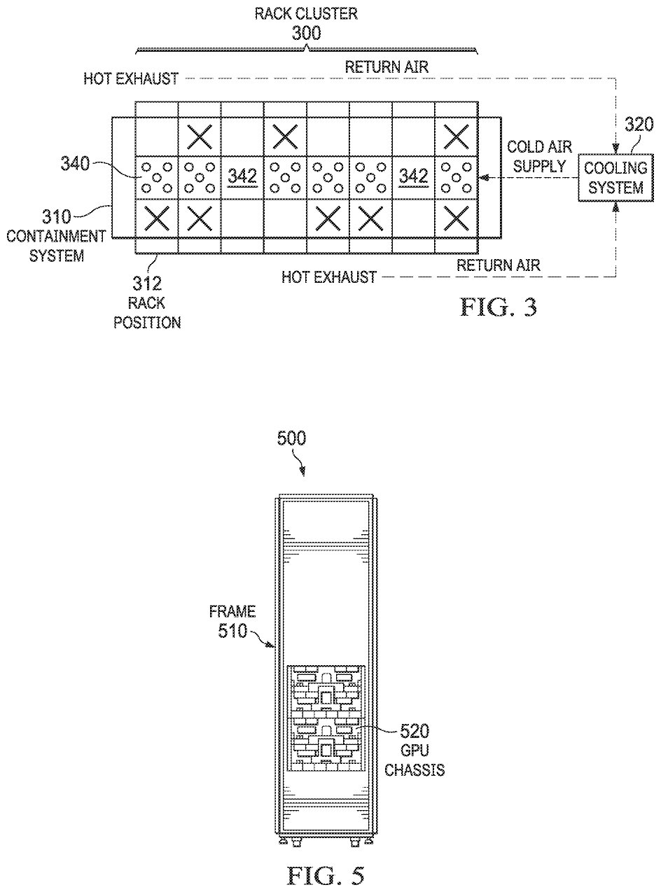

FIG. 3 illustrates a diagram of an embodiment of a rack cluster constructed according to the principles of the disclosure;

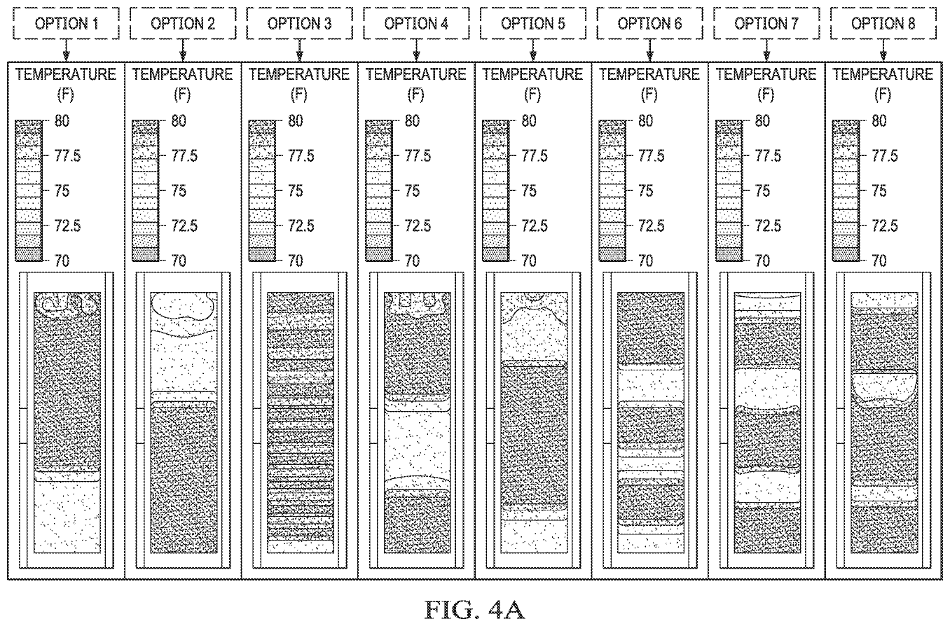

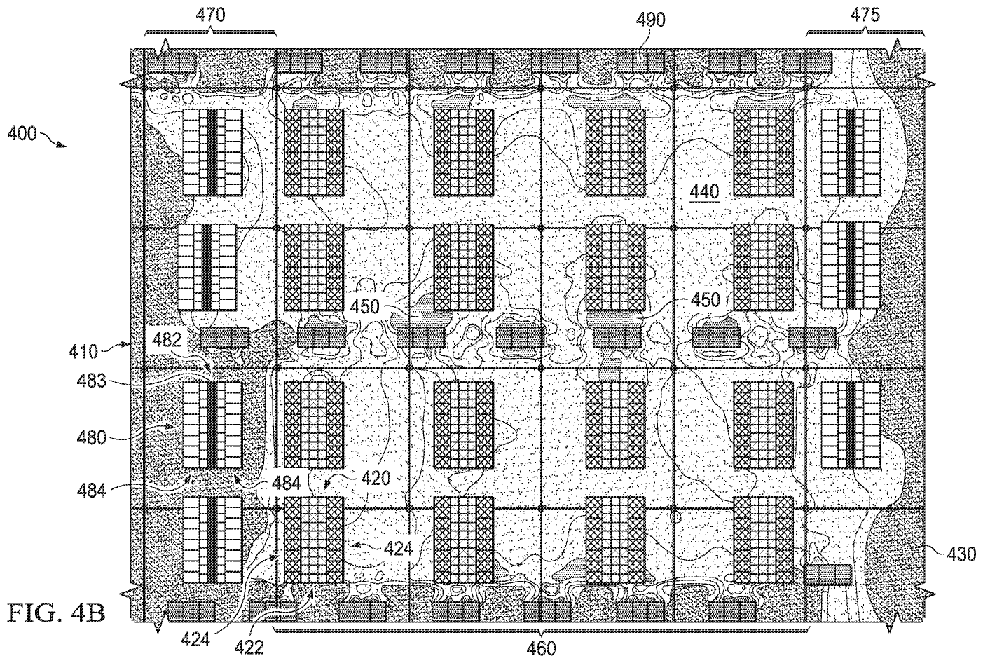

FIG. 4A illustrates examples of heat diagrams from Computational Fluid Dynamic (CFD) modelling that can be used to determine placement of components within a server rack according to the principles of the disclosure;

FIG. 4B illustrates an example of a diagram from CFD modelling that can be used to determine placement of rack clusters within a data center according to the principles of the disclosure;

FIG. 5 illustrates a diagram of an embodiment of a high density server rack that can be used in rack clusters according to the principles of the disclosure;

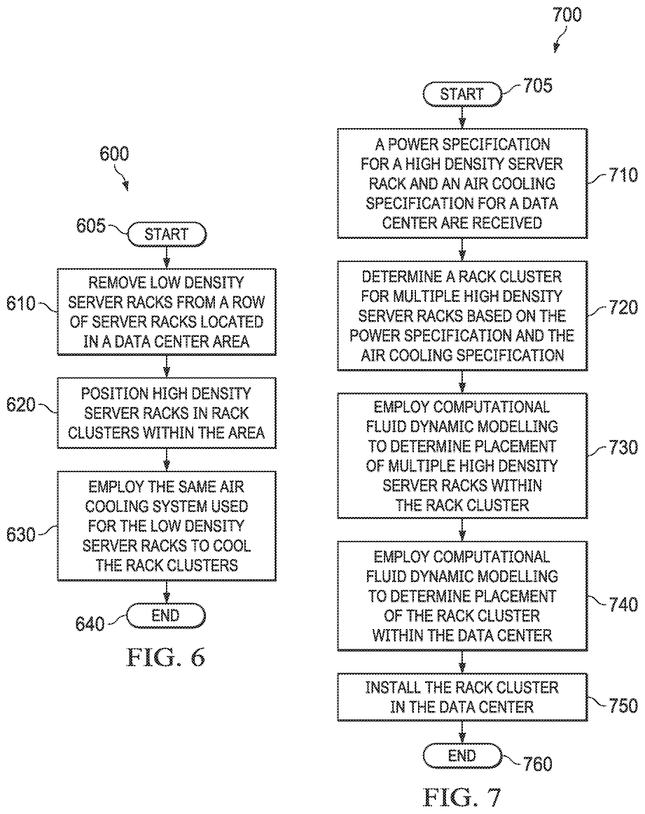

FIG. 6 illustrates a flow diagram of an embodiment of a method of converting an area of a data center from low density server racks to high density server racks carried out according to the principles of the disclosure; and

FIG. 7 illustrates a flow diagram of an example of a method of installing air-cooled, high density server racks within a data center carried out according to the principles of the disclosure.

### DETAILED DESCRIPTION

Though improvements have been made in CPU based servers, the demand for increased processing power has resulted in data centers that employ Graphics Processing Unit (GPU) driven servers, i.e., GPU data centers. While a GPU driven server typically includes a CPU, a GPU driven server employs a GPU or GPUs to execute instructions in parallel to process data and perform tasks. GPU driven servers and data centers are beneficial for companies looking for increased processing power to operate their businesses. With an increase in processing power, however, there is typically an increase in power demand. For example, the power demand for a typical CPU based server rack can range between 5 to 15 kW and the power demand for a GPU driven server rack of the same physical dimensions can be 35 kW or greater. An increase in the processing power and power demand for a server rack results in an increase in heat generated and a corresponding increase in cooling requirements for the server rack.

While air cooling may be sufficient for server racks having a power demand up to approximately 20 kW, server racks having a higher power demand, such as some GPU driven server racks (GPU racks), may require other cooling techniques and schemes to remove heat, such as a rear door heat exchanger that uses a liquid coolant. Removing heat from server racks having a high power demand can be critical since this can hinder upgrading the processing power of a data center. For example, cooling design modifications, such as liquid cooling, closely coupled cooling methods, and further containment for efficiency, may be required in order to have sufficient cooling for server racks having a higher power demand. This is especially true when the physical space of a data center is filled with GPU racks that can generate substantially more heat compared to CPU racks. However, changing the cooling design for a data center can be problematic to an operating environment as server racks with a higher power demand are deployed.

Accordingly, the disclosure provides in one more embodiments a method of converting a data center, or at least a portion thereof, from air-cooled, low power density server racks (i.e., low density server racks) to air-cooled, high power density server racks (i.e., high density server racks). A low density server rack is defined herein as a server rack having a power demand of 20 kW or less, and a high density server rack is a server rack having a power demand greater than 20 kW. Advantageously, the same air cooling system that is used for the low density server racks is also used for the high density server racks. As such, the disclosed method can be used to change an area of a data center from low density server racks, such as CPU based server racks (CPU racks), to GPU racks having greater processing power while still employing the type of cooling system that is used for the low density server racks. An area in a data center previously used for low density computing can now be more easily converted to a high density computing area. In addition to converting, the principles of the disclosure can be used to design and construct a data center for high density server racks, such as a GPU based data center, in a new space using air cooling without having to use another type of cooling. The disclosure therefore provides in one or more embodiments a mechanism, a rack cluster that allows flexibility in managing, upgrading, and building data centers for high density server racks while still employing air cooling.

In various embodiments the disclosure introduces rack clusters for converting and designing data centers. A rack cluster is a configuration of server racks or server rack positions having a maximum power demand. Rack clusters are established based on power specifications of the server racks and air cooling specifications of the data center. The rack clusters are used to create power demand blocks that can be replicated within the data center even when the power demand of the individual server racks used in the rack cluster change. As such, in one more embodiments the disclosure provides modifying or designing a data center based on air-cooled rack clusters; especially for high density server racks. This differs from the present method of designing data centers by determining how many server racks can fit within a physical area of a data center and then determining the amount and type of cooling needed for the individual server racks.

In at least one embodiment, a rack cluster can be used with a containment area of a data center that separates cold air supply from hot exhaust. The cold air supply is inlet cold air from the cooling system of the data center and the hot exhaust is hot air that is the return air for the cooling system. The cooling system can be an air conditioning system that provides the cold air via, for example, a cold aisle. In one or more embodiment, the cold aisle can include perforated tiles of a raised floor. In at least one embodiment, the cold air can also be provided via a cold aisle that includes vents and ducts of an overhead air conditioning system. The amount of cold air provided for the cold air supply can be at least partly controlled by the placement of the vents or perforated tiles and the open area percentage of the vents or perforated tiles from which the cold air supply is provided.

In some embodiments, the placement and open area percentage of the vents or perforated tiles is changed when converting from low density server racks to high density server racks. Using perforated tiles as an example, the open area percentage of the perforated tiles can change for the conversion from a standard open area of low flow perforated tiles, to a standard open area of high flow perforated tiles. For example, perforated tiles can be changed from a standard open area of 25 percent to a standard open area of 68 percent. In at least one embodiment, the open area percentages and changes can be based on the location of the high power demand racks within a rack cluster and the amount of heat to remove (e.g., heat generated) for the high density racks. Blanking panels and air dams can also be added to control airflow in the containment system for the rack cluster to provide sufficient cooling in some embodiments.

As noted above, an example of a high density server rack is a GPU rack. The GPU racks and GPU data centers can offer more computing power in less physical space compared to CPU based racks and data centers. Additionally, instead of just a mere increase in computing power versus space, the GPU racks and resulting GPU data centers can provide the needed Floating Point Operations per Second (FLOPS) for artificial intelligence (AI), high performance computing, and can be defined based on workload.

The GPU racks can be high-density (HD) GPU racks that include high performance GPU compute nodes and storage nodes. The high performance GPU compute nodes can be servers designed for general-purpose computing on graphics processing units (GPGPU) to accelerate deep learning applications. For example, the GPU compute nodes can be servers of the DGX product line from Nvidia Corporation of Santa Clara, California. A version of the DGX product line, DGX-1, is used herein as an example of a GPU compute node in different following examples.

The compute density provided by the HD GPU racks is advantageous for AI computing and GPU data centers directed to AI computing. For example, the GPU data centers employing HD GPU racks can provide the storage and networking needed to support large-scale deep neural network (DNN) training that powers software development for autonomous vehicles, internal AI for companies, and robotics development. The HD-GPU racks can be used with reactive machines, autonomous machines, self-aware machines, and self-learning machines that all require a massive compute intensive server infrastructure. Accordingly, in one or more embodiments the rack clusters can allow installing high density server racks that are solely air-cooled, HD GPU racks. FIG. 1 and FIG. 2 provide an example of converting at least an area of a data center from low density server racks to air-cooled, high density server racks using rack clusters.

FIG. 1 illustrates a diagram of an embodiment of a data center 100. The data center 100 includes a data hall 110, a control room 120, a mechanical electrical plumbing (MEP) plant 130, and a cooling system 140. One skilled in the art will understand that the data center 100 includes additional components or systems that are often used with data centers but are not illustrated or discussed with respect to FIG. 1.

In one or more embodiment, the data hall 110 includes multiple rows, Rows 1 to N, of low density servers positioned in racks. The low density server racks can be CPU racks. The racks can be standard sized racks that are commercially available and typically used in data centers. Rows 1 and 2 are used an examples of the other Rows 3 to N and will be discussed in more detail as representative rows. A single rack position of Row 2 having a low density server rack is denoted as rack position 111.

In the illustrated embodiment, Rows 1 and 2, are located in a containment area wherein a containment system 112 separates a cold air supply provided by the cooling system 140 from the hot exhaust of the server racks in Rows 1 and 2. The containment system 112 can be a conventional containment system employed in data centers. In one or more embodiments, the data hall 110 can include other containment areas having containment systems. In various embodiments, a containment area can include only two rows of racks.

In one or more embodiment, the cooling system 140 provides cold air for the cold air supply and receives the hot exhaust as return air. In various embodiments, the cold air can be provided via perforated tiles 113 of a raised floor (not shown in FIG. 1) in the data hall 110. The placement, number, and opening area percentage of the perforated tiles 113 can vary depending on airflow requirements. In some embodiments, the cold air can also be provided from the cooling system 140 via overhead vents. The perforated tiles and raised floor will be used hereinafter as an example of distributing the cold air supply.

In one or more embodiment, the cooling system 140 can include multiple air cooling systems and be located within the data hall 110 as shown, located external to the data hall 110, or can be a combination thereof with portions located internal and external to the data hall 110. At least a portion of the cooling system 140 can be controlled by the MEP plant 130 according to environmental controls generated by a controller in the control room 120. The MEP plant 130 can receive the environmental controls and provide operating controls based thereon to operate the cooling system 140 and adjust the environment of the data hall 110. The MEP plant 130 can at least include typical systems and controls that are employed in MEP plants of conventional data centers. Accordingly, in one or more embodiment the cooling system 140 can include multiple levels of cooling systems to control the environment in the data hall 110 and the environmental controls can be generated to cooperatively control these multiple cooling systems. The multiple levels can be arranged according to cooling areas or designated areas to cool within the data hall 110 in at least one embodiment. For example, the cooling system 140 can include a cooling system for the entire data hall 110 and a computer room air conditioning (CRAC) unit or units for different areas within the data hall 110, such as the containment area. In one or more embodiment, the cooling system 140 can also include a cooling system for the facility in which the data center 100 is located. The facility cooling system can include a chiller and can be controlled by the MEP plant 130. In at least one embodiment, each of the Rows 1 and 2 include multiple racks that fill each rack position of the Rows 1 and 2, such as rack position 111. Each of the multiple racks can be a low density server rack and is an air-cooled rack wherein heat from the racks is removed via air moving from the cold air supply to the hot exhaust.

In at least one embodiment, the cooling system 140 and containment system 112 are sufficient to cool the low density server racks of Rows 1 and 2. However, converting to high density server racks typically requires a rework for cooling the server racks by adding additional cooling. An additional method of cooling, such as a liquid cooling could be required. An example of a system for liquid cooling includes a rear door heat exchanger. Adding liquid cooling requires providing a liquid, such as water, to Rows 1 and 2 for cooling. This can be disruptive, especially when the data center 100 does not already have a water supply.

FIG. 2 illustrates a diagram of an embodiment of a data hall of a data center having air-cooled, high density server racks according to the principles of the disclosure. The data hall 110 of the data center 100 of FIG. 1 is used as an example to demonstrate converting an area of a data center from low density server racks to high density server racks positioned within rack clusters. In one more embodiments, the high density server racks can be GPU racks. The physical space of Rows 1 and 2 of the data hall 110 is shown in FIG. 2 while other portions of the data center 100, such as additional rows, the control room, and the MEP plant are not illustrated in FIG. 2 for ease of discussion.

In the illustrated embodiment, two rack clusters, rack cluster 210 and rack cluster 220, are being used in the physical space of Rows 1 and 2. Each of the rack clusters has a maximum power demand that is determined based on a power specification for a high density server rack to be used in the rack clusters 210, 220, and an air cooling specification for the data center 100. In one or more embodiment, the maximum power demand can be the same for each rack cluster within the data center 100, such as rack clusters 210, 220. In some embodiments, the maximum power demand can vary for rack clusters within the data center 100. For example, the rack cluster 210 can have a different maximum power demand than for rack cluster 220.

Though high density server racks are in the physical space of Rows 1 and 2, no other cooling system or systems besides air cooling are added for the high density server racks. Instead, the air cooling system used for the low density server racks, cooling system 140, is used for the high density server racks. In some embodiments, adjustments to the cooling system 140 are made to provide additional airflow and/or cooler air for the high density server racks of the rack clusters 210, 220. In one or more embodiment, the flow rate, such as measured by cubic feet per minute (CFM) or cubic meter per hour (M³/h), can be increased to increase airflow through the high density server racks of the rack clusters 210, 220. In one or more embodiment, the airflow can be increased via changing the perforated tiles, such as from low flow perforated tiles to high flow perforated tiles. In one or more embodiment, the airflow can be increased by, or can also be increased by, increasing the pressure of the air.

Additionally, in one or more embodiments the rack system used with the low density server racks in FIG. 1 does not have to be changed for the new high density server racks of the rack clusters 210, 220. Instead, the same racks can be used. This allows using standard racks for both low and high density server racks without requiring the added cost of a new racking system. Each of the rack clusters 210, 220, in FIG. 2 includes 16 rack positions or spaces for server racks. In various embodiments, the number of rack positions in a rack cluster can vary depending on the installation. Additionally, the number of rack positions that are filled for each rack cluster can vary in one or more embodiments. In FIG. 2, the rack positions for each of the rack clusters 210, 220, are separated by a cold aisle into two rows. Rack position 212 of rack cluster 210 is denoted as an example of the rack positions of the rack clusters 210, 220. In some embodiments, one or more of the rack positions of the rack clusters 210, 220, can be the rack positions of Rows 1 to 2 of FIG. 1. For example, rack position 212 can be the same as rack position 111. FIG. 5 provides an embodiment of a high density server rack that can placed in the rack position 111 or rack position 212.

In one or more embodiment, each rack cluster 210, 220, can be within their own containment system, containment systems 230 and 240, as illustrated in FIG. 2. In some embodiments, a single containment system can be used for multiple rack clusters. Accordingly, in one or more embodiment the same containment system as used with the low density server racks can also be used in some embodiments. Within the cold aisle of the containment systems 230, 240, are perforated tiles 213 and 223 for distribution of the cold air supply. In some embodiments, the perforated tiles 213 can be the same tiles and arranged the same way as the perforated tiles 223. In other embodiments, the perforated tiles 213 can differ from the perforated tiles 223 in characteristics and arrangement. The perforated tiles 213, 223, are arranged with two tiles located between each row of the high density server racks of the rack clusters 210, 220. The number of tiles and the ratio of perforated tiles to server rack in a rack cluster can vary in different embodiments. In some embodiments, the ratio of perforated tiles to high density server racks in a rack cluster can be 10 to 8. As illustrated in FIG. 4B, in one or more embodiment three rows of tiles can be used between rows of server racks of rack clusters.

In FIG. 2 the rack clusters 210, 220, are positioned in straight rows. In some embodiments, the rack clusters 210, 220, can be arranged without being in rows. In at least one embodiment, the distribution of static air pressure in the data hall 110, such as represented by CFD modelling, can be used to determine the arrangement of the rack clusters.

As noted above, each of the rack clusters 210, 220, have 16 rack positions. In some embodiments, some of the rack positions may not have a server rack, i.e., some rack positions can be open. FIG. 3 provides an example of such an embodiment.

FIG. 3 illustrates a diagram of an embodiment of rack cluster 300 constructed according to the principles of the disclosure. The rack cluster 300 is with a containment system 310 and is shown in the environment of a data center that includes a cooling system 320. In some embodiments, a rack cluster may not be within a containment system. The rack cluster 300 includes multiple rack positions, in which one of the rack positions is denoted as rack position 310 for reference. In one more embodiment, the rack positions of the rack cluster 300 are separated into two rows with a single row of tiles between the two rows. In one or more embodiment, the configuration of the rack clusters can change per the data center environment and is dependent on the power demand of the rack clusters and high density racks.

As illustrated in FIG. 3, in one or more embodiment a fewer number of high density server racks can be used than the number of available rack positions in the rack cluster 300. Eight rack positions, denoted by an “X”, of the total of sixteen rack positions are filled with a high density server rack in the example of FIG. 3. In at least one embodiment, the number of high density server racks in the rack cluster 300 can vary based on such factors as power demand, heat generated, cooling capacity, etc. In one or more embodiment, the cooling capacity can include multiple factors, such as amount of airflow (CFM or M³/h), intake air temperature (SAT), delta T (rise of the temperature of the air).

Additionally, in at least one embodiment the arrangement of the high density server racks within the rack cluster 300 and containment system 310 can vary to distribute cooling requirements within the containment system 310 and allow for sufficient airflow for cooling of the high density server racks. The placement of perforated tiles, such as perforated tile 340, and the open area percentage of the openings of the perforated tiles can also vary in different embodiments to provide the sufficient amount of airflow for cooling. Some solid tiles, such as tiles 342, or directional perforated tiles can be used in in one or more embodiments to assist in directing the cold air to high density server racks. In at least one embodiment, CFD modelling can be used to determine placement of the tiles and the types of tiles that are used with the rack cluster 300 to provide sufficient airflow for cooling.

In one or more embodiment, CFD modelling can be used to determine optimum placement of components within a rack. The components include, for example, compute nodes, data storage or memory, switches, etc. Using GPU racks as an example of high density server racks, FIG. 4A illustrates heat diagrams from CFD modelling of different GPU rack options, Option 1 to Option 8, that demonstrate the temperature and distribution of heat at the back of the cabinets for each of the server rack options. Option 3 exhibits more uniform temperature distribution. In at least one embodiment, CFD modelling can be one factor considered for placement of compute nodes within server racks. Other factors, such as cable management can also be considered in various embodiments. In at least one embodiment, different configurations of high density server racks within a rack cluster can be used to obtain optimum cooling for a rack cluster. For example, the arrangement of components within a server rack can vary for the different server racks within a rack cluster. Option 1 may be placed in a rack position next to option 2. Thus, in one or more embodiment the air cooling requirement for the total rack cluster can be considered for placement of server racks within a rack cluster; even over the individual rack designs. In at least one embodiment, CFD modelling can also be used to determine placement of rack clusters within an area of a data center. For example CFD modelling can indicate an optimal positioning of the rack clusters 210, 220, within the data hall 110.

FIG. 4B illustrates a diagram 400 generated from CFD modelling that in at least one embodiment can assist in positioning rack clusters within a data center 410. Diagram 400 represents the distribution of air pressure underneath a raised floor within the data center 410 and can be used to verify sufficient airflow for cooling rack clusters according to operating parameters of the data center 410. For other data centers, the distribution of air pressure can vary due to the characteristics of each particular data center.

In at least one embodiment, the data center 410 has a maximum power capacity of 4,500 kW available for cooling and powering rack clusters, and the pressure distribution diagram 400 is used to place sixteen rack clusters with a power demand of 280 kW in the data center 410 at locations having a minimum static pressure of 0.05 inches per water column (INWC) under the raised floor for sufficient air flow to cool the rack clusters. One of the sixteen rack clusters is denoted as rack cluster 420 in FIG. 4B as a representative of the sixteen rack clusters to be positioned in the data center 410. In at least one embodiment, three rows of perforated tiles 422 can be used between two rows of server racks 424 of the rack cluster 420.

In addition to the sixteen rack clusters, the pressure distribution diagram 400 also illustrates additional rack clusters that may be added to the data center 410 in the future. For example, one or more of the sixteen rack clusters may have an actual power demand that is less than 280 kW. In at least one embodiment, one or more additional rack clusters can be added to utilize the maximum power capacity of 4,500 kW and minimize stranded capacity. Rack cluster 480 is denoted in FIG. 4B as a representative of these additional rack clusters. Three rows of perforated tiles 482 are used in between two rows of server racks 484 of the rack cluster 480. One row of the perforated tiles, designated as 483, are solid.

In this illustrated embodiment, the pressure distribution diagram 400 illustrates the distribution of air pressure underneath the raised floor of the data center 410 as three different pressures that are relative to each other. The minimum static pressure 440 having a value of 0.05 INWC for this embodiment is shown. Additionally, a higher static pressure 430 having a value of 0.06 INWC is represented along with a lower static pressure 450. In at least one embodiment, the lower static pressure 450 can correspond to the location of fans under the raised floor in the data center 410, wherein air velocity is high and the air pressure is lower compared to the minimum static pressure 440. Fan 490 is denoted in FIG. 4B as a representative of the fans in the data center 410. A central area 460 of the data center 410 corresponds to the minimum static pressure 440, and edge areas 470, 475, of the data center 410 correspond to the high static pressure 430 as air is pushed close to the walls of the data center 410. In at least one embodiment, the pressure distribution diagram 400 verifies that the sixteen rack clusters can be placed in the central area 460 and have the minimum static pressure 440.

In one or more embodiment, the pressure distribution diagram 400 can assist in selecting the perforated tiles needed to provide the air flow for cooling the rack clusters. For example, if an open area percentage of 68 percent is selected for the perforated tiles 422 to manage the air flow needed for cooling the rack cluster 420 with the minimum static pressure 440 in the central area 460, perforated tiles having a lower open percentage, such as 40 or 50 percent, may be selected in areas with higher static pressure 430, such as for the perforated tiles 482. In at least one embodiment, different open area percentage of tiles can be selected to correspond to different power demands of the rack clusters.

As noted above, an example of a high density server rack is a GPU driven server rack. FIG. 5 illustrates an embodiment of an air-cooled GPU server rack 500 that can be used in data centers and when converting from low density server racks to high density server racks. The GPU server rack 500 includes a frame 510 and GPU chassis 520. In FIG. 5, the back side of the GPU server rack 500 is illustrated. The frame 510 can be a conventional frame of a typical rack system used in data centers. The GPU server rack 500 can be placed in a rack position of a rack cluster, such as in rack position 212 of FIG. 2 or 310 of FIG. 3. The GPU chassis 520 fits within the frame 510 and includes compute nodes and storage nodes. Various embodiments of GPU chassis designs can be used that include servers based on GPU compute nodes defined based on workloads. In one or more embodiments the compute nodes can be high performance GPU compute nodes, such as one of the DGX product lines available from Nvidia Corporation. In different embodiments, the GPU server rack 500 can include more than one GPU chassis.

In at least one embodiment, the GPU server rack 500 can be a 30 kW GPU server rack that is air-cooled. In at least one embodiment, a 30 kW GPU server rack can be cooled by 2,400 CFM of standard air having 40 degrees Fahrenheit delta T difference between supply and return air. In at least one embodiment, high density GPU server racks with a different power demand can be used. For example, a 45 kW GPU air-cooled rack can be used. In at least one embodiment, each of the compute nodes has at least one fan, i.e., their own fan, which pulls air through the GPU server rack 500 from the front side to the back side, such as cold air from the cold air supply provided by cooling system 140. In one or more embodiment, the physical structure of compute nodes within the GPU server rack 500 can contribute to cooling of higher compute capacity using air.

FIG. 6 illustrates a flow diagram of an embodiment of a method 600 of converting an area of a data center from low density server racks to high density server racks. The area, such as a data hall 110, in the data center employs an air cooling system for cooling the low density server racks. In at least one embodiment, the air cooling system can be solely used for cooling the high density server racks after the conversion. The method 600 begins in a step 605.

In a step 610, low density server racks are removed from a row or rows of server racks located in the area. In one or more embodiment, the row of server racks can be in a containment area that separates a cold air supply and hot exhaust. In at least one embodiment, the cold air supply can be delivered via a cold air aisle that has perforated tiles and/or overhead vents.

In a step 620, high density server racks positioned within rack clusters are placed in the physical space of the row of server racks. In at least one embodiment, the number of high density server racks in the rack cluster can be less than the total number of low density server racks in the rows. The high density server racks can be distributed within the rack cluster in one or more embodiment wherein at least some rack positions of the rack cluster are not filled with the high density server racks. In at least one embodiment, positioning of components within the high density racks and of the high density server racks within the rack clusters can be evaluated and adjusted. In at least one embodiment, CFD modelling can be employed on a processor to determine placement of multiple high density server racks within the rack cluster and the arrangement of components within the high density server rack itself. In one or more embodiment, employing the CFD modelling can be iterative processes.

In a step 630, the air cooling system that was used for cooling the low density server racks is employed for cooling the rack cluster. In one or more embodiment, air cooling can be adjusted to correspond to power requirements of racks and results of CFD modelling. In at least one embodiment, adjusting using the CFD modelling can be performed iteratively. In various embodiments, the air cooling adjustments can include changing tile types, placement of tiles within a containment area, arranging tiles to reduce or increase airflow, etc. When adding the high density server racks, an open area percentage of at least some perforated tiles located within the cold air supply of the containment area can be changed in one or more embodiments. The method 600 ends in a step 640.

FIG. 7 illustrates a flow diagram of an example of a method 700 of installing air-cooled, high density server racks within a data center. The high density server racks can be CPU or GPU racks. The method 700 begins is a step 705.

In a step 710, a power specification for a high density server rack and an air cooling specification for a data center are received. In at least one embodiment, the data center is designed for low density servers and high density server racks are being added to the data center. High density server racks can replace or supplement the low density server racks in the data center. In at least one embodiment, high density server racks having different power specifications are employed in the same data center.

A rack cluster for multiple high powered racks based on the power specification and the air cooling specification is determined in a step 720. In at least one embodiment, the rack cluster can be selected to have a maximum power demand for air cooling. For example, a rack cluster can be designed with a maximum power demand of 280 kW using air cooling, such as via floor tiles. The rack cluster can have rack positions for 16 server racks for an average of 17.5 kW per rack if all 16 rack positions are filled. If high density server racks with a power specification of 35 kW are used, then a maximum of eight of the 35 kW racks can be used in this example rack cluster having a maximum power demand of 280 kW. As such, in one or more embodiments the maximum power demand for a rack cluster can be less than the total required power if each rack position of a rack cluster is filled with a server rack of the power specification. In at least one embodiment, the maximum power demand of a rack cluster is half of the power specification times the number of rack positions of the rack cluster.

CFD modelling is employed on a processor in a step 730 to determine placement of multiple high density server racks within the rack cluster. FIG. 4A illustrates an example of CFD modelling that can be employed in at least one embodiment. In at least one embodiment, air cooling can be adjusted to correspond to power requirements of racks and results of the CFD modelling. In at least one embodiment, the air cooling adjustments can include changing tile types, placement of tiles within a containment area, arranging tiles to reduce or increase airflow, etc.

CFD modelling is also employed in a step 740 to determine placement of the rack cluster within the data center. FIG. 4B illustrates an example of CFD modelling that can be employed in at least one embodiment. In at least one embodiment, adjustments can be made in response to CFD models to calibrate on updated data. In one or more embodiment, the CFD modelling can be used to determine the placement for multiple rack clusters within the data center. FIG. 4B noted above provides an example. Multiple iterations can be used in at least one embodiment to determine or optimize the placement of racks within a rack cluster and rack clusters within the data center. For example, the rack clusters can be moved to various locations and tested using CFD modelling to determine the optimum location for air cooling of rack clusters within the data center and verify sufficient airflow for cooling. In at least one embodiment, adjustments to the airflow can include changing tile types, arranging tiles to reduce or increase airflow, etc.

In a step 750, the rack cluster is installed in the data center according to the CFD modelling. In at least one embodiment, the rack cluster can be installed at the determined location within the data center according to conventional installation procedures. In one or more embodiments, multiple rack clusters can be installed in the data center according to the placement determined by the CFD modelling. The method 700 ends in a step 760.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

It is noted that as used herein and in the appended claims, the singular forms “a”, “an”, and “the” include plural referents unless the context clearly dictates otherwise.

A portion of the above-described apparatus, systems or methods may be embodied in or performed by various digital data processors or computers, wherein the computers are programmed or store executable programs of sequences of software instructions to perform one or more of the steps of the methods. The software instructions of such programs may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein. The data storage media can be part of or associated with the digital data processors or computers.

Those skilled in the art to which this application relates will appreciate that other and further additions, deletions, substitutions and modifications may be made to the described aspects. It is also to be understood that the terminology used herein is for the purpose of describing particular aspects only, and is not intended to be limiting, since the scope of the present disclosure will be limited only by the claims.

Various aspects of the disclosure can be claimed including the systems and methods as noted in the summary. Each of the aspects noted in the summary may have one or more of the elements of the dependent claims presented below in combination.

What is claimed is:

1. A data center, comprising:
a processor to use one or more computational fluid dynamics (CFD) models to indicate a placement of one or more servers within one or more server racks to substantially maintain a temperature within the one or more server racks during operation without using additional cooling sources.

2. The data center as recited in claim 1, wherein the one or more server racks has a front side facing a cold air supply and a back side, and each of the one or more server racks is solely cooled by air moving therethrough from the front side to the back side, wherein the one or more server racks further comprise a compute node having at least one fan that pulls the cold air supply from the front side through to the back side.

3. The data center as recited in claim 2, wherein the one or more server racks are arranged in a rack cluster including rack positions and each of the one or more server racks are positioned in a different one of the rack positions.

4. The data center as recited in claim 3, wherein the rack cluster includes two rows of rack positions and the cold air supply is provided between the two rows.

5. The data center as recited in claim 3, wherein a first cooling source comprises a cooling system that provides a cold air supply, and wherein the rack cluster is at least partially positioned within a containment system and the containment system isolates the cold air supply at the front side of each of the one or more server racks from a hot exhaust at the back side of each of the one or more server racks.

6. The data center as recited in claim 5, wherein the rack cluster has a different power demand as an additional rack cluster in the containment system.

7. The data center as recited in claim 1, further comprising a raised floor having perforated tiles that allow distribution of a cold air supply at a front side of each of the one or more server racks.

8. The data center as recited in claim 7, wherein the processor is further to use the one or more CFD models to select an open area percentage of the perforated tiles to control air flow of the cold air supply.

9. The data center as recited in claim 1, wherein the one or more server racks includes one or more GPU driven servers.

10. The data center as recited in claim 1, wherein the one or more server racks are rated at greater than 20 kW.

11. A processor, comprising:
one or more circuits to use one or more computational fluid dynamics (CFD) models to indicate a placement of one or more servers within one or more server racks to substantially maintain a temperature within the one or more server racks during operation without using additional cooling sources.

12. The processor of claim 11, wherein the one or more circuits further use the one or more CFD models to determine placement of one or more perforated tiles relative to the one or more server racks.

13. The processor of claim 12, wherein the one or more circuits further use the one or more CFD models to determine a design of the one or more perforated tiles to be placed relative to the one or more server racks.

14. The processor of claim 13, wherein the design comprises an open area percentage of at least some of the one or more perforated tiles.

15. The processor of claim 11, wherein the one or more circuits further use the one or more CFD models to determine placement of the rack cluster within an area of a data center.

16. The processor of claim 11, wherein the one or more circuits further use the one or more CFD models to determine placement of the one or more server racks within a rack cluster.

17. The processor of claim 11, wherein the one or more server racks are rated at greater than 35 kW.

18. The processor of claim 11, wherein the one or more circuits further receive a power specification for a high density server rack and an air cooling specification for a data center.

19. The processor of claim 18, wherein the one or more circuits further identify a first rack cluster of the one or more rack clusters for multiple high density racks based on the power specification and the air cooling specification, and arrange, using the one or more CFD models, the multiple high density racks in the first rack cluster.

20. A processor comprising:
one or more circuits to use one or more computational fluid dynamics (CFD) models to indicate a placement of one or more servers racks within one or more rack clusters to substantially maintain a temperature within the one or more server racks during operation without using additional cooling sources.
